(19) United States
(12) Patent Application Publication
(10) Pub. No.: US 2026/0353932 A1
(43) Pub. Date: Nov. 5, 2026

(54) DISPLAY PANEL AND DISPLAY DEVICE

(71) Applicant: WUHAN TIANMA MICROELECTRONICS CO., LTD., Wuhan (CN)

(72) Inventor: Fei LI, Wuhan (CN)

(73) Assignee: WUHAN TIANMA MICROELECTRONICS CO., LTD., Wuhan (CN)

(21) Appl. No.: 19/725,004

(22) Filed: Jun. 30, 2026

(30) Foreign Application Priority Data
Dec. 8, 2025 (CN) 202511842548.5

(51) Int. Cl. H10K 59/122; H10K 59/35

(52) U.S. Cl. CPC H10K 59/122; H10K 59/353

(57) ABSTRACT

A display panel includes a substrate and a pixel definition layer disposed on one side of the substrate, and the pixel definition layer has a plurality of sub-pixel openings for arranging sub-pixels, and the pixel definition layer is provided with a plurality of partition portions; and for at least some pairs of adjacent sub-pixels, the partition portions provided between the two adjacent sub-pixels are in a quantity of at least three.

### CROSS REFERENCE OF RELATED APPLICATION

The present application claims the priority to Chinese Patent Application No. 202511842548.5, titled “DISPLAY PANEL AND DISPLAY DEVICE”, filed on Dec. 8, 2025 with the China National Intellectual Property Administration (CNIPA), which is incorporated herein by reference in its entirety.

### FIELD

The present disclosure relates to the field of display technology, and in particular to a display panel and a display device.

### BACKGROUND

In a Tandem Organic Light Emitting Diode, also known as Tandem OLED, a plurality of light-emitting units are vertically stacked through transparent connecting layers. Tandem OLEDs are mainly applied to lighting and high-end display applications. The core structure thereof includes double or multiple layers of light-emitting units connected by one or more charge generation layers (CGLs), utilizing the pn junction tunneling effect to achieve high efficiency carrier injection.

### SUMMARY

In view of the above problems, the present disclosure provides a display panel and a display device, achieving the purpose of improving the display effect of the display panel. The specific solutions are as follows.

In a first aspect, the present disclosure provides a display panel including: a substrate; and a pixel definition layer disposed on one side of the substrate, and the pixel definition layer has a plurality of sub-pixel openings for arranging sub-pixels, and the pixel definition layer is provided with a plurality of partition portions;
in one embodiment, for at least some pairs of adjacent sub-pixels, the partition portions provided between the two adjacent sub-pixels are in a quantity of at least three.

In a second aspect, the present disclosure provides a display panel including: a substrate; and a pixel definition layer disposed on one side of the substrate, and the pixel definition layer has a plurality of sub-pixel openings for arranging sub-pixels, and the pixel definition layer is provided with a plurality of partition portions surrounding the respective sub-pixels; and the sub-pixels include target sub-pixels, and the partition portions include first partition portions surrounding the respective target sub-pixels; each of the first partition portions includes two notches; and a line connecting centers of the two notches in each of some of the first partition portions intersects with a line connecting centers of the two notches in each of others of the first partition portions.

In a third aspect, the present disclosure provides a display device including the display panel according to any one of the above aspects.

### BRIEF DESCRIPTION OF THE DRAWINGS

The above and other features, advantages and aspects of various embodiments of the present disclosure will become more apparent from the following detailed description when taken in conjunction with the accompanying drawings. Throughout the drawings, identical or similar reference numerals denote identical or similar elements. The drawings are schematic and elements and components are not necessarily drawn to scale.

FIG. 1 is a schematic structural diagram of a display panel provided in an embodiment of the present disclosure;

FIG. 2 is a schematic cross-sectional diagram of a display panel provided in an embodiment of the present disclosure;

FIG. 3 is a schematic cross-sectional diagram of another display panel provided in an embodiment of the present disclosure;

FIG. 4 is a schematic cross-sectional diagram of yet another display panel provided in an embodiment of the present disclosure;

FIG. 5 is a partial structural diagram of a display area in a display panel provided in an embodiment of the present disclosure;

FIG. 6 is a schematic cross-sectional diagram along the FF′ direction in FIG. 5 provided in an embodiment of the present disclosure;

FIG. 7 is a partial diagram of the periphery of a support portion in FIG. 6 provided in an embodiment of the present disclosure;

FIG. 8 is a schematic cross-sectional diagram along the EE′ direction in FIG. 7 provided in an embodiment of the present disclosure;

FIG. 9 is a schematic cross-sectional diagram along the HH′ direction in FIG. 7 provided in an embodiment of the present disclosure;

FIG. 10 is a partial diagram of sub-pixels not adjacent to the support portion in FIG. 6 provided in an embodiment of the present disclosure;

FIG. 11 is a partial structural diagram of a display area in another display panel provided in an embodiment of the present disclosure;

FIG. 12 is a schematic diagram of a leakage current path of a blue sub-pixel provided in an embodiment of the present disclosure;

FIG. 13 is a schematic diagram of a leakage current path of a red sub-pixel provided in an embodiment of the present disclosure;

FIG. 14 is a partial structural schematic diagram of a display area in yet another display panel provided in an embodiment of the present disclosure; and

FIG. 15 is a schematic structural diagram of a display device provided in an embodiment of the present disclosure.

### DETAILED DESCRIPTION OF THE EMBODIMENTS

The embodiments of the present disclosure are described below with reference to the accompanying drawings in the embodiments of the present disclosure. The terms used in the embodiments of the present disclosure are only for explaining the specific embodiments of the present disclosure, and are not intended to limit the present disclosure. As will be appreciated by a person skilled in the art, the embodiments provided by the embodiments of the present disclosure are equally applicable to similar technical problems with the development of technology and the emergence of new scenarios.

For better understanding of the above objectives, features, and advantages of the present disclosure, the present disclosure is further described in detail below in conjunction with the accompanying drawings and specific implementations.

The directional words used in the present disclosure are based on the relative positional relationships shown in the drawings and should not be construed as absolute limitations of the present disclosure.

Various modifications and variations can be made in the present disclosure without departing from the spirit or scope of the present disclosure. Therefore, the present disclosure is intended to cover modifications and variations of the present disclosure that fall within the scope of the claims (some embodiments) and equivalents thereof. The embodiments provided by the present disclosure can be combined with each other when there is no contradiction.

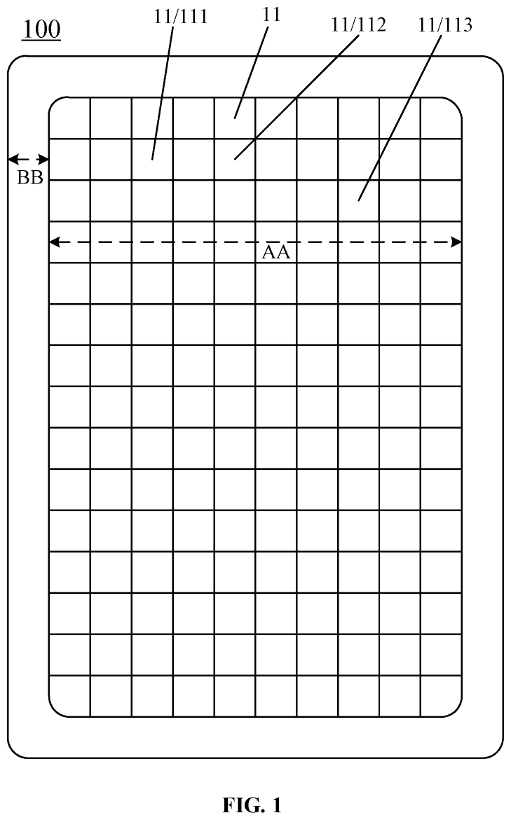

Refer to FIG. 1, which is a schematic structural diagram of a display panel provided in an embodiment of the present disclosure. The display panel 100 provided in an embodiment of the present disclosure is divided into a display area AA and a non-display area BB that at least partially surrounds the display area AA. The non-display area BB is typically the bezel region of the display panel 100.

In one embodiment of the present disclosure, the display area AA includes a plurality of sub-pixels 11. Exemplarily, the plurality of sub-pixels 11 may include first sub-pixels 111 and second sub-pixels 112, and the first sub-pixels 111 and the second sub-pixels 112 emit light of different colors. For example, the first sub-pixel 111 is an R sub-pixel, and the second sub-pixel 112 is a G sub-pixel; the first sub-pixel 111 emits red light, and the second sub-pixel 112 emits green light. In one embodiment, in order to achieve full-color display of the display panel 100, the plurality of sub-pixels 11 may further include third sub-pixels 113, and the third sub-pixels 113 are B sub-pixels for emitting blue light.

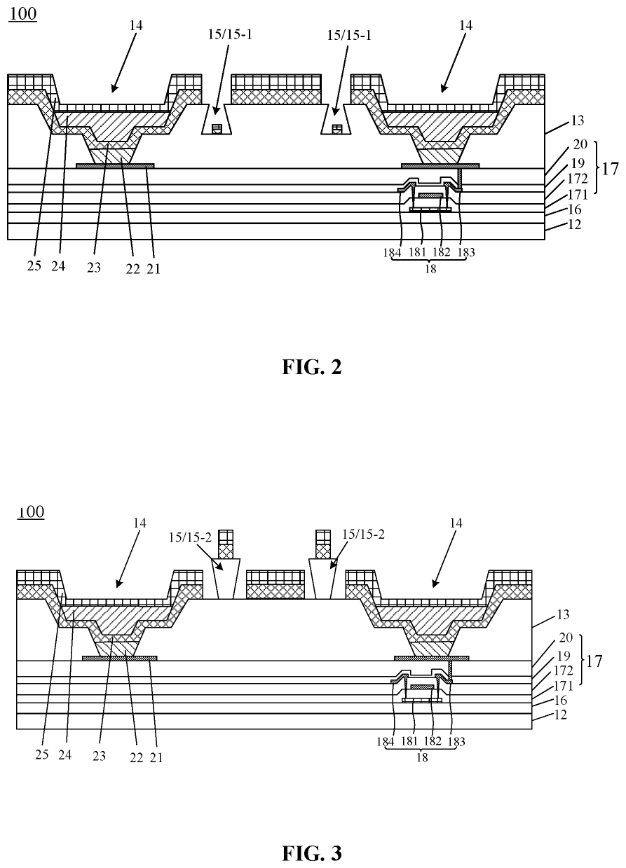

Refer to FIG. 2, which is a schematic cross-sectional diagram of a display panel provided in an embodiment of the present disclosure. The display panel 100 provided in an embodiment of the present disclosure includes a substrate 12, and a pixel definition layer 13 disposed on one side of the substrate 12; the pixel definition layer 13 has a plurality of sub-pixel openings 14 for arranging sub-pixels 11; the pixel definition layer 13 is provided with a plurality of partition portions 15.

In one embodiment of the present disclosure, the display panel 100 may further include a buffer layer 16 and an array layer 17 disposed between the substrate 12 and the pixel definition layer 13.

The array layer 17 includes but is not limited to a plurality of thin film transistors 18, a passivation layer 19, and a planarization layer 20. The thin film transistor 18 may include an active layer 181, a gate 182, a source 183, a drain 184. The array layer 17 may further include a gate insulating layer 171 arranged between the active layer 181 and the gate 182, and an interlayer insulating layer 172 arranged between the gate 182 and the source 183 and between the gate 182 and the drain 184. The passivation layer 19 is arranged on a side of the source 183 and the drain 184 away from the interlayer insulating layer 172, the planarization layer 20 is arranged on a side of the passivation layer 19 away from the interlayer insulating layer 172, and the pixel definition layer 13 is arranged on a side of the planarization layer 20 away from the substrate 12. In the embodiment of the present disclosure, description is made by taking the case where the source 183 and the drain 184 are disposed in the same layer as an example.

The pixel definition layer 13 has a multi-layer structure in FIG. 2, which is not described in detail here, and only one thin film transistor 18 is illustrated as an example in FIG. 2. Circuit structures such as a pixel circuit for driving the sub-pixels 11 to emit light are composed of the thin film transistors 18 and other components and elements.

In one embodiment, the display panel 100 provided by the embodiment of the present disclosure may further include an encapsulation layer. The encapsulation layer includes but not limited to a first inorganic encapsulation layer, an organic encapsulation layer, and a second inorganic encapsulation layer arranged in sequence on the pixel definition layer 13, and the encapsulation layer includes but is not limited to a thin film encapsulation layer (TFE).

In one embodiment, the substrate 12 is a substrate base made of a flexible insulating material, having characteristics such as being stretchable, bendable, or foldable, and the material thereof includes but is not limited to polyimide material (abbreviated as PI) or polycarbonate material (abbreviated as PC) or polyethylene terephthalate material (abbreviated as PET), etc.

In one embodiment, the buffer layer 16 includes but is not limited to an inorganic material layer or an organic material layer. The material of the inorganic material layer includes but is not limited to silicon oxide, silicon nitride, silicon oxynitride, aluminum oxide, or aluminum nitride, etc., and the material of the organic material layer includes but is not limited to acrylic or PI, etc. In the embodiments of the present disclosure, description is made by taking the buffer layer being an organic material layer as an example.

As shown in FIG. 2, description is made by taking the partition portion 15 provided on the pixel definition layer 13 being a groove portion 15-1 as an example. Normally, the groove portion 15-1 does not penetrate through the pixel definition layer 13.

FIG. 3 is a schematic cross-sectional diagram of another display panel provided in an embodiment of the present disclosure. As shown in FIG. 3, description is made by taking the partition portion 15 provided on the pixel definition layer 13 being a protrusion portion 15-2 as an example.

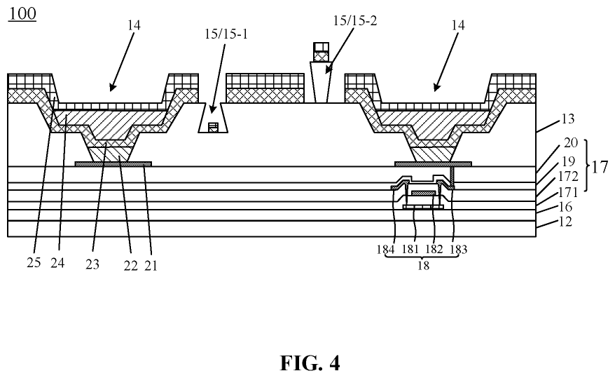

FIG. 4 is a schematic cross-sectional diagram of yet another display panel provided in an embodiment of the present disclosure. As shown in FIG. 4, some of the partition portions 15 are groove portions 15-1 provided on the pixel definition layer 13, and others of the partition portions 15 are protrusion portions 15-2 provided on the pixel definition layer 13.

In view of the display panel 100 shown in FIG. 2 and FIG. 3, in the embodiments of the present disclosure, the partition portions 15 are groove portions 15-1 or protrusion portions 15-2 provided on the pixel definition layer 13. In view of the display panel 100 shown in FIG. 4, in the embodiments of the present disclosure, the partition portions 15 on the pixel definition layer 13 include both the groove portions 15-1 and the protrusion portions 15-2.

As shown in FIG. 2 to FIG. 4, the sub-pixel 11 provided by the embodiment of the present disclosure includes: a first electrode 21 disposed on a side of the substrate 12; a first light-emitting layer 22 disposed on a side of the first electrode 21 away from the substrate 12; a charge generation layer 23 disposed on a side of the first light-emitting layer 22 away from the first electrode 21; a second light-emitting layer 24 disposed on a side of the charge generation layer 23 away from the first light-emitting layer 22; and a second electrode 25 disposed on a side of the second light-emitting layer 24 away from the charge generation layer 23.

In an embodiment of the present disclosure, the first electrode 21 can be understood as the anode of the sub-pixel 11, and the second electrode 25 can be understood as the cathode of the sub-pixel 11. The charge generation layer 23 at least includes an N-type doped charge generation layer and a P-type doped charge generation layer, respectively serving as a transparent anode and a transparent cathode. In one embodiment, the N-type doped charge generation layer is arranged adjacent to the first light-emitting layer 22, and the P-type doped charge generation layer is arranged adjacent to the second light-emitting layer 24, thereby achieving connection of the double layers of light-emitting units and achieving high efficiency carrier injection by utilizing the p-n junction tunneling effect.

During research, it is found that in existing display panels, each sub-pixel 11 is correspondingly provided with partition portion(s) 15, and there are only two partition portions 15 between two adjacent sub-pixels 11; or some sub-pixels 11 are not correspondingly provided with partition portions 15. Thus the leakage current path between sub-pixels 11 in existing display panels is still relatively short, and the problem of unintended lighting of sub-pixels 11 still exists, degrading the display effect of the display panel.

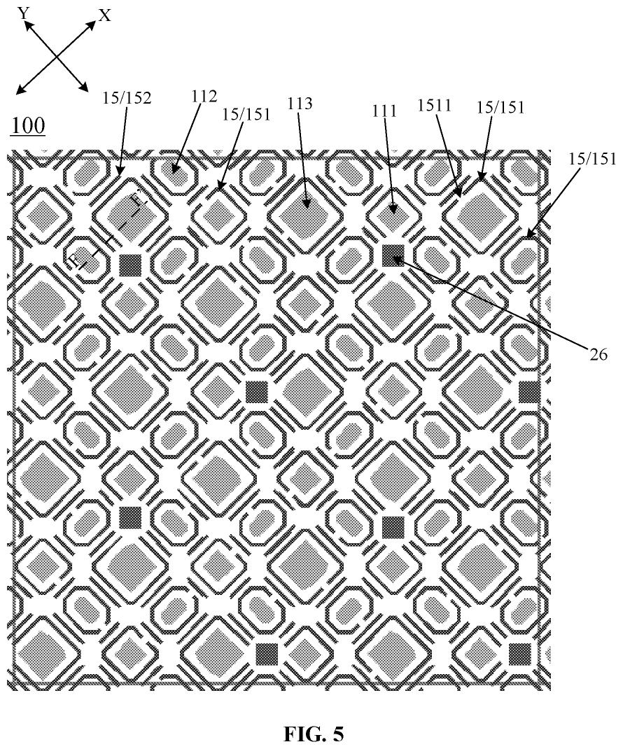

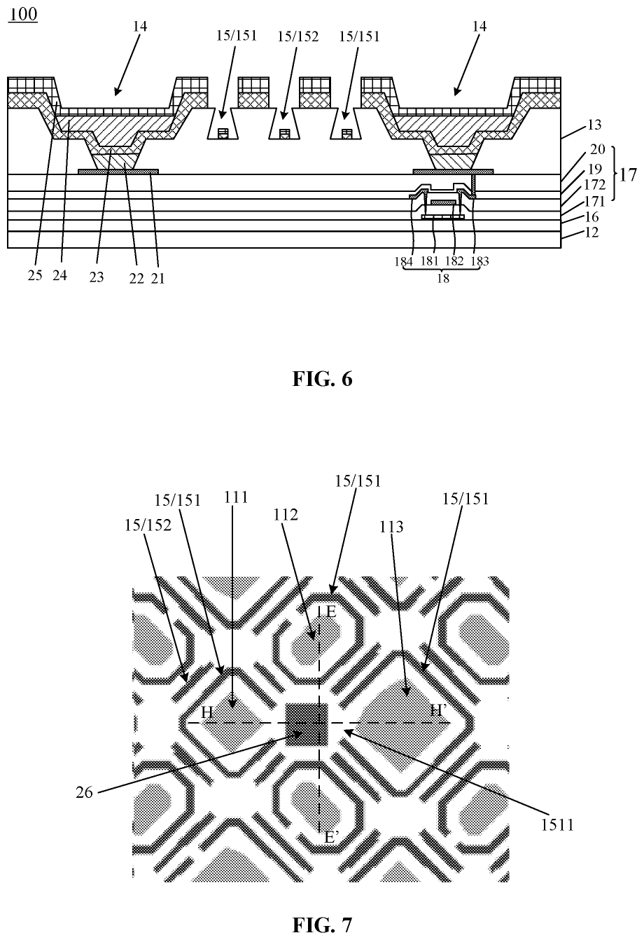

To address this, referring to FIG. 5 which is a partial structural schematic diagram of a display area in a display panel provided in an embodiment of the present disclosure, and FIG. 6 which is a schematic cross-sectional diagram along the FF′ direction in FIG. 5, in the display panel 100 provided in an embodiment of the present disclosure, at least three partition portions 15 are provided between at least some adjacent two sub-pixels 11. This extends the leakage current path between the adjacent two sub-pixels 11, improves leakage current uniformity, thereby resolving the problem of unintended lighting of sub-pixels 11 to the greatest extent, and improving the display effect of the display panel 100.

In one embodiment, as shown in FIG. 5, the sub-pixels 11 include first sub-pixels 111, second sub-pixels 112, and third sub-pixels 113.

The i-th row of the sub-pixels includes the first sub-pixels 111 and the second sub-pixels 112 alternately arranged along a first direction X; the (i+1)-th row of the sub-pixels includes the second sub-pixels 112 and the third sub-pixels 113 alternately arranged along the first direction X; the j-th column of the sub-pixels includes the first sub-pixels 111 and the second sub-pixels 112 alternately arranged along a second direction Y; the (j+1)-th column of the sub-pixels includes the second sub-pixels 112 and the third sub-pixels 113 alternately arranged along the second direction Y; the first direction X intersects with the second direction Y, and i and j are both any positive integers.

The embodiment of the present disclosure provides only one possible arrangement of the sub-pixels 11, and the embodiments of the present disclosure are also applicable to sub-pixels 11 in other arrangements.

In an optional embodiment of the present disclosure, as shown in FIG. 5 and FIG. 6, the partition portions 15 in the display panel 100 provided according to the embodiment of the present disclosure include first partition portions 151 and second partition portions 152.

The first partition portion 151 includes a notch 1511, and the first partition portion 151 surrounds the sub-pixel 11.

The second partition portion 152 is disposed between the first partition portions 151 corresponding to at least some pairs of adjacent sub-pixels 11.

In one embodiment, in the embodiment of the present disclosure, each sub-pixel 11 is surrounded by a first partition portion 151, and each first partition portion 151 has a notch 1511, to slow down the leakage current from this sub-pixel 11 to other sub-pixels, alleviate the problem of unintended lighting of other sub-pixels 11 when this sub-pixel 11 is lit, thereby improving the display effect of the display panel 100. Further, a second partition portion 152 is further provided between the first partition portions 151 corresponding to some pairs of adjacent sub-pixels 11. In this way, there are actually three partition portions 15 between the two adjacent sub-pixels 11, extending the leakage current path between the adjacent two sub-pixels 11, improving leakage current uniformity, thereby resolving the problem of unintended lighting of sub-pixels 11 to the greatest extent, and improving the display effect of the display panel 100.

The three partition portions 15 between the two adjacent sub-pixels 11 are composed of three parts: the first part is a part of the first partition portion 151 corresponding to a first sub-pixel that faces a second sub-pixel; the second part is the second partition portion 152, and the third part is a part of the first partition portion 151 corresponding to the second sub-pixel that faces the first sub-pixel, thereby satisfying the requirement that there are three partition portions 15 between these adjacent two sub-pixels 11.

In one embodiment, as shown in FIG. 5, the second partition portion 152 is in a bar shape. In other implementations, the second partition portion 152 may be in other shapes such as a curved shape, a zigzag shape, etc., to extend the leakage current path between the two adjacent sub-pixels 11 as much as possible.

If the second partition portion 152 is in a bar shape, the length of the second partition portion 152 is greater than or equal to the size of the notch 1511. The size of the notch 1511 can be understood as the length of the connecting line between the two ends of the notch 1511.

In the case where the notch 1511 directly faces the second partition portion 152, in a direction perpendicular to the lengthwise direction of the second partition portion 152, the orthographic projection of the second partition portion 152 must completely cover the notch 1511, forcing the leakage current bypass the second partition portion 152 and thus extending the leakage current path; if the second partition portion 152 only partially overlaps the notch 1511, the leakage current path cannot be extended at the non-overlapping portion.

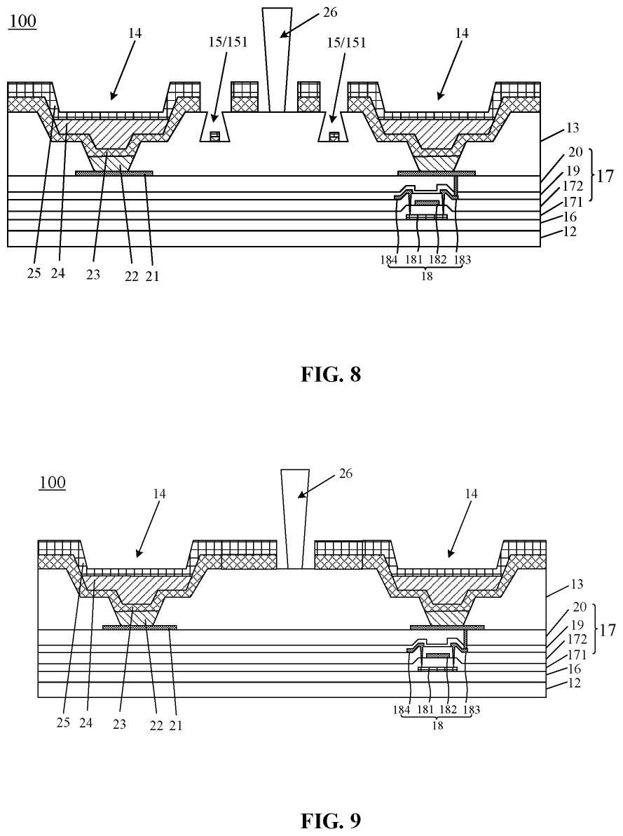

In an optional embodiment of the present disclosure, referring to FIG. 7 which is a partial schematic diagram of the periphery of the support portion in FIG. 6 provided in an embodiment of the present disclosure, FIG. 8 which is a schematic cross-sectional diagram along the EE′ direction in FIG. 7 provided in an embodiment of the present disclosure, and FIG. 9 which is a schematic cross-sectional diagram along the HH′ direction in FIG. 7 provided in an embodiment of the present disclosure, the display panel 100 provided in an embodiment of the present disclosure further includes a plurality of support portions 26.

In a plurality of the first partition portions 151 adjacent to the support portion 26, the notches 1511 of at least some of the first partition portions 151 directly face the support portion 26.

In one embodiment, in the embodiment of the present disclosure, the support portion 26 is also referred to as a PS column in the field. By arranging the notches 1511 of at least some of the first partition portions 151 directly facing the support portion 26, the design margin of the support portion 26 can be increased, and the support portion 26 can be prevented from being positioned in the region where the partition portions 15 are disposed, which would affect the morphology of the partition portions 15 and the height and strength of the support portion 26.

Normally, a plurality of sub-pixels 11 are arranged around one support portion 26. As shown in FIG. 7, four sub-pixels 11, i.e., a first sub-pixel 111, a first second sub-pixel 112, a third sub-pixel 113, and a second second sub-pixel 112, are arranged in sequence around the support portion 26. In the direction of the surrounding arrangement, it only needs to ensure that the notches 1511 of the first partition portions 15 corresponding to any two adjacent sub-pixels 11 among these four sub-pixels 11 do not both directly face the support portion 26. For example, the notches 1511 of the first partition portions 15 corresponding to the first sub-pixel 111 and the first second sub-pixel 112 do not both directly face the support portion 26. If, among these four sub-pixels 11 in the direction of the surrounding arrangement, the notches 1511 of the first partition portions 15 corresponding to two adjacent sub-pixels 11 both directly face the support portion 26, the leakage current path between the two sub-pixels 11 will be greatly shortened, contradicting the objective of the embodiments of the present disclosure, which aims to extend the leakage current path.

Based on this, in the embodiment of the present disclosure, the notches 1511 of the first partition portions 151 corresponding to the sub-pixels 11 disposed on two opposite sides of the support portion 26 are arranged to directly face the support portion 26. In this way, the support portion 26 can serve as a component for extending the leakage current path between these two notches 1511. An optimal implementation is to arrange the notches 1511 of the first partition portions 151 corresponding to the sub-pixels 11 disposed on two opposite sides in the lengthwise direction of the support portion 26 to directly face the support portion 26, thereby extending the leakage current path between these two notches 1511 to the greatest extent.

Exemplarily, as shown in FIG. 7, the sub-pixels 11 include first sub-pixels 111, second sub-pixels 112, and third sub-pixels 113.

The first sub-pixels 111 are red sub-pixels, the second sub-pixels 112 are green sub-pixels, and the third sub-pixels 113 are blue sub-pixels.

Among the red sub-pixel, the green sub-pixels, and the blue sub-pixel adjacent to the support portion 26, the notch 1511 of the first partition portion 151 corresponding to the red sub-pixel directly faces the support portion 26, the notch 1511 of the first partition portion 151 corresponding to the blue sub-pixel directly faces the support portion 26, and the notches 1511 of the first partition portions 151 corresponding to the green sub-pixels directly face the second partition portion 152.

Further considering that when the blue sub-pixel is lit, the green sub-pixel is prone to unintended lighting, and when the red sub-pixel is lit, the green sub-pixel is prone to unintended lighting, therefore, in the case where the notches 1511 of the first partition portions 151 corresponding to the red sub-pixel and the blue sub-pixel directly face the support portion 26, the notches 1511 of the first partition portions 151 corresponding to the green sub-pixels are arranged to directly face the second partition portion 152. This increases the distance between the notch 1511 of the first partition portion 151 corresponding to the red sub-pixel and the notch 1511 of the first partition portion 151 corresponding to the green sub-pixel, thereby extending the leakage current path between the red sub-pixel and the green sub-pixel; and increase the distance between the notch 1511 of the first partition portion 151 corresponding to the blue sub-pixel and the notch 1511 of the first partition portion 151 corresponding to the green sub-pixel, thereby extending the leakage current path between the blue sub-pixel and the green sub-pixel.

In an optional embodiment of the present disclosure, as shown in FIG. 5, the second partition portions 152 are arranged between the adjacent red sub-pixels and green sub-pixels, and the second partition portions 152 are arranged between the adjacent blue sub-pixels and green sub-pixels.

In one embodiment, in the embodiment of the present disclosure, considering that when the red sub-pixel is lit, the green sub-pixel is prone to unintended lighting, the second partition portion 152 is provided between the red sub-pixel and the green sub-pixel, to extend the leakage current path between the red sub-pixel and the green sub-pixel, and avoid the problem of unintended lighting of the other sub-pixel 11 when one of the red sub-pixel and the green sub-pixel is lit.

Further considering that when the blue sub-pixel is lit, the green sub-pixel is also prone to unintended lighting, the second partition portion 152 is provided between the blue sub-pixel and the green sub-pixel, to extend the leakage current path between the blue sub-pixel and the green sub-pixel, and avoid the problem of unintended lighting of the other sub-pixel 11 when one of the blue sub-pixel and the green sub-pixel is lit, thereby improving the display effect of the display panel 100 to the greatest extent.

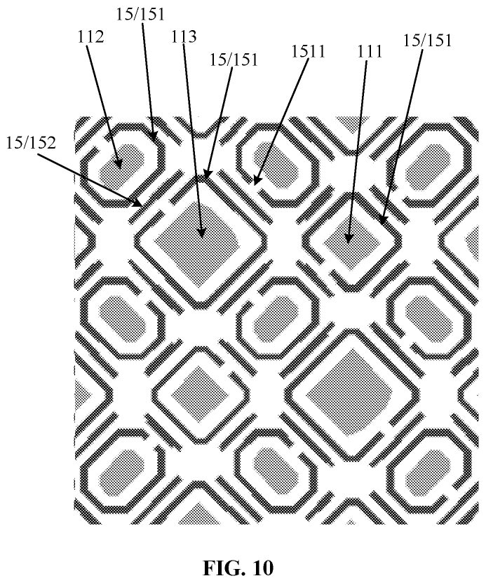

In an optional embodiment of the present disclosure, referring to FIG. 10 which is a partial schematic diagram of sub-pixels not adjacent to the support portion in FIG. 5 provided in an embodiment of the present disclosure, in the display panel 100 provided in an embodiment of the present disclosure, among the sub-pixels 11 not adjacent to the support portion 26, the notches 1511 of the first partition portions 151 corresponding to any two adjacent sub-pixels 11 do not directly face each other.

In one embodiment, in the embodiment of the present disclosure, considering that in the case where the partition portions 15 are provided, the current transmission path between sub-pixels 11 mainly goes through the notches 1511. Therefore, if among the sub-pixels 11 not adjacent to the support portion 26, the notches 1511 of the first partition portions 151 corresponding to two adjacent sub-pixels 11 directly face each other, then the length of the current transmission path between these two sub-pixels 11 would, in one embodiment, be the distance between the two notches 1511, which contradicts the purpose of the embodiments of the present disclosure to extend the leakage current path. Accordingly, in the embodiment of the present disclosure, for the sub-pixels 11 not adjacent to the support portion 26, the notches 1511 of the first partition portions 151 corresponding to two adjacent sub-pixels 11 do not directly face each other, to extend the leakage current path between these two notches 1511 to the greatest extent, resolve the problem of unintended lighting of sub-pixels 11, and further improve the display effect of the display panel 100 to the greatest extent.

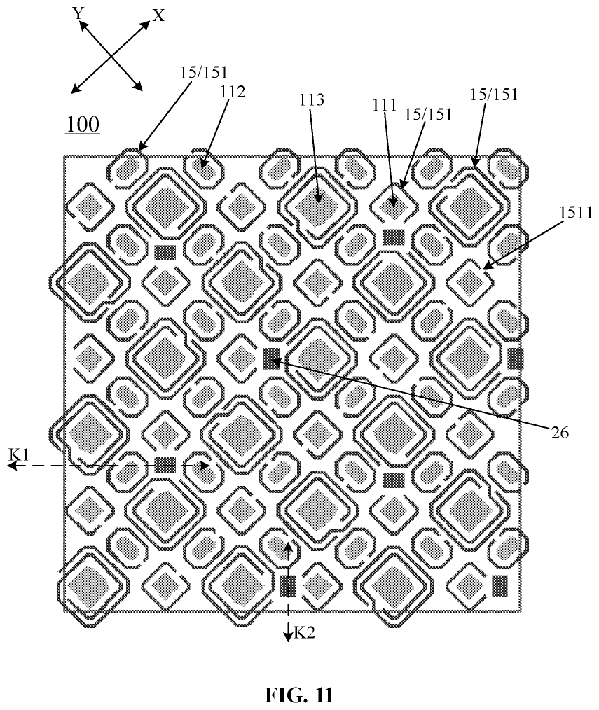

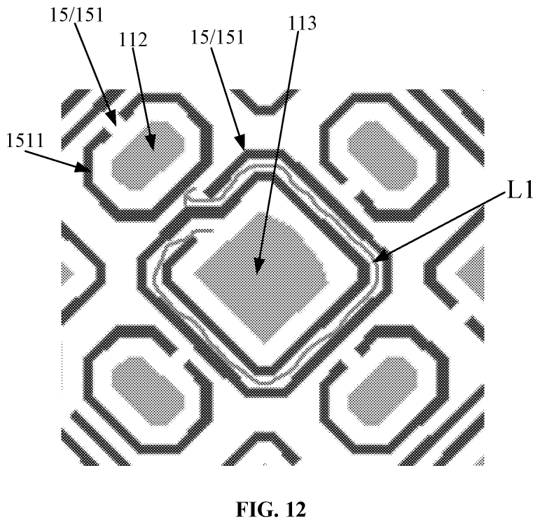

In an optional embodiment of the present disclosure, referring to FIG. 11 which is a partial structural schematic diagram of a display area in another display panel provided in an embodiment of the present disclosure, in the display panel 100 provided in an embodiment of the present disclosure, at least three partition portions 15 are provided between at least some pairs of adjacent sub-pixels 11, to extend the leakage current path between the adjacent two sub-pixels 11, improve leakage current uniformity, thereby resolving the problem of unintended lighting of sub-pixels 11 to the greatest extent, and improving the display effect of the display panel 100.

In one embodiment, as shown in FIG. 11, the sub-pixels 11 include first sub-pixels 111, second sub-pixels 112, and third sub-pixels 113.

The i-th row of the sub-pixels includes the first sub-pixels 111 and the second sub-pixels 112 alternately arranged along a first direction X; the (i+1)-th row of the sub-pixels includes the second sub-pixels 112 and the third sub-pixels 113 alternately arranged along the first direction X; the j-th column of the sub-pixels includes the first sub-pixels 111 and the second sub-pixels 112 alternately arranged along a second direction Y; the (j+1)-th column of the sub-pixels includes the second sub-pixels 112 and the third sub-pixels 113 alternately arranged along the second direction Y; the first direction X intersects with the second direction Y, and i and j are both any positive integers.

The embodiment of the present disclosure provides only one possible arrangement of the sub-pixels 11, and the embodiments of the present disclosure are also applicable to sub-pixels 11 in other arrangements.

In an optional embodiment of the present disclosure, as shown in FIG. 11, the partition portions 15 in the display panel 100 provided in the embodiment of the present disclosure include first partition portions 151.

Each of the first partition portions 151 includes a notch 1511 and surrounds the sub-pixel 11.

Some of the first partition portions 151 are arranged in a spiral shape.

As shown in FIG. 11, the spiral-shaped first partition portion 151 can be understood as using one end of the first partition portion 151 as a starting end, surrounding the sub-pixel 11 in a clockwise or counterclockwise direction, forming the partition portion 15 with the head and tail not connected, with the starting end located inside the spiral-shaped first partition portion 151, and the ending end located outside the spiral-shaped first partition portion 151.

In one embodiment, in the embodiment of the present disclosure, each sub-pixel 11 is surrounded by a first partition portion 151, and each first partition portion 151 has a notch 1511, to slow down the leakage current from this sub-pixel 11 to other sub-pixels, alleviate the problem of unintended lighting of other sub-pixels 11 when this sub-pixel 11 is lit, thereby improving the display effect of the display panel 100. Further, some of the first partition portions 151 are arranged in a spiral shape, and based on the number of turns of the spiral-shaped first partition portion 151 surrounding the sub-pixel 11, the number of partitions 15 between two adjacent sub-pixels 11 can be flexibly defined, and there are actually three partition portions between the two adjacent sub-pixels 11 at this part, extending the leakage current path between the adjacent two sub-pixels, improving leakage current uniformity, thereby resolving the problem of unintended lighting of sub-pixels 11 to the greatest extent, and improving the display effect of the display panel 100.

The three partition portions 15 between the two adjacent sub-pixels 11 are composed of two parts: the first part is the two portions of the spiral-shaped first partition portion 151 corresponding to the first sub-pixel that face the second sub-pixel, and the second part is the portion of the first partition portion 151 corresponding to the second sub-pixel that faces the first sub-pixel, thereby satisfying the requirement that there are three partition portions 15 between these adjacent two sub-pixels 11.

In one embodiment, as shown in FIG. 11, the sub-pixels 11 in the display panel 100 provided by the embodiment of the present disclosure include first sub-pixels 111, second sub-pixels 112, and third sub-pixels 113.

The first sub-pixels 111 are red sub-pixels, the second sub-pixels 112 are green sub-pixels, and the third sub-pixels 113 are blue sub-pixels.

The first partition portions 151 corresponding to the blue sub-pixels are each arranged in a spiral shape.

In one embodiment, at least three partition portions 15 are provided between the blue sub-pixel and the green sub-pixel, at least three partition portions 15 are provided between the blue sub-pixel and the red sub-pixel, and two partition portions 15 are provided between the red sub-pixel and the green sub-pixel.

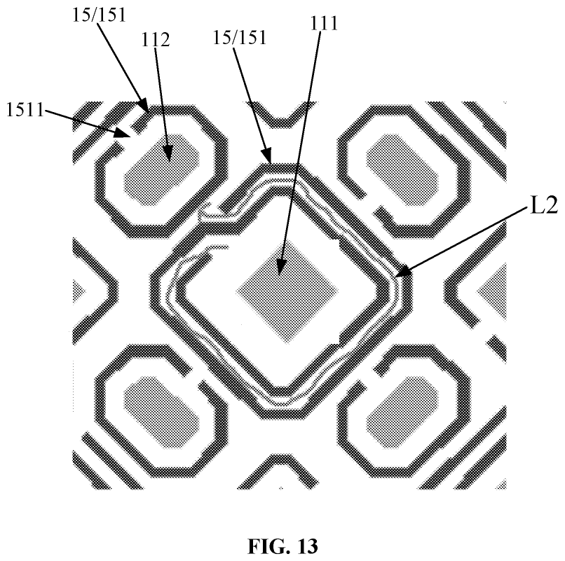

In one embodiment, in the embodiment of the present disclosure, considering that when the blue sub-pixel is lit, the unintended lighting of the red sub-pixel and/or the green sub-pixel is likely to occur, the first partition portion 151 corresponding to the blue sub-pixel is set to a spiral shape. Reference is made to FIG. 12, which is a schematic diagram of a leakage current path of a blue sub-pixel provided in an embodiment of the present disclosure. As shown in FIG. 12, based on the spiral-shaped first partition portion 151, the leakage current path L1 of the blue sub-pixel can at least completely go around the blue sub-pixel once, and the leakage current path of the blue sub-pixel can be extended to the extreme, to extend the leakage current path between the blue sub-pixel and the red sub-pixel and between the blue sub-pixel and the green sub-pixel, and when the blue sub-pixel is lit, the problem of unintended lighting of the red sub-pixel and/or the green sub-pixel is resolved, thereby improving the display effect of the display panel 100 to the greatest extent.

In one embodiment, in the display panel 100 provided by the embodiment of the present disclosure, the sub-pixels 11 include first sub-pixels 111, second sub-pixels 112, and third sub-pixels 113.

The first sub-pixels 111 are red sub-pixels, the second sub-pixels 112 are green sub-pixels, and the third sub-pixels 113 are blue sub-pixels.

The first partition portions 151 corresponding to the red sub-pixels are each arranged in a spiral shape.

In one embodiment, at least three partition portions 15 are provided between the red sub-pixel and the green sub-pixel, at least three partition portions 15 are provided between the red sub-pixel and the blue sub-pixel, and two partition portions 15 are provided between the green sub-pixel and the blue sub-pixel.

In one embodiment, in the embodiment of the present disclosure, considering that when the red sub-pixel is lit, the unintended lighting of the blue sub-pixel and/or the green sub-pixel is likely to occur, the first partition portion 151 corresponding to the red sub-pixel is set to a spiral shape. Reference is to FIG. 13, which is a schematic diagram of a leakage current path of a red sub-pixel provided in an embodiment of the present disclosure. As shown in FIG. 13, based on the spiral-shaped first partition portion 151, the leakage current path L2 of the red sub-pixel can at least completely go around the red sub-pixel once, and the leakage current path of the red sub-pixel can be extended to the extreme, to extend the leakage current path between the red sub-pixel and the blue sub-pixel and between the red sub-pixel and the green sub-pixel, and when the red sub-pixel is lit, the problem of unintended lighting of the blue sub-pixel and/or the green sub-pixel is resolved, thereby improving the display effect of the display panel 100 to the greatest extent.

Considering that when the display panel 100 displays a white frame, the green light accounts for about 70% of the brightness, the red light accounts for about 20% of the brightness, and the blue light accounts for about 10% of the brightness, therefore, if the green sub-pixels encounter unintended lighting, the impact on the display effect of the display panel 100 is the greatest. In view of this, in the embodiment of the present disclosure, the first partition portion 151 corresponding to the red sub-pixel can also be arranged in a spiral shape, and the first partition portion 151 corresponding to the blue sub-pixel is arranged in a spiral shape, to extend the leakage current paths of the red sub-pixel and the blue sub-pixel to the greatest extent, thereby extending the leakage current paths from the red sub-pixel to the green sub-pixel and from the blue sub-pixel to the green sub-pixel, and maximally avoiding the problem of unintended lighting of the green sub-pixel when the red sub-pixel and/or the blue sub-pixel are lit, thereby improving the display effect of the display panel 100 to the greatest extent.

In an optional embodiment of the present disclosure, as shown in FIG. 11, the display panel 100 provided by the embodiment of the present disclosure further includes a plurality of support portions 26; the lengthwise direction of some of the support portions 26 is different from that of others.

In one embodiment, in the embodiment of the present disclosure, when the first partition portions 151 corresponding to some of the sub-pixels 11 are each arranged in a spiral shape, more space between the sub-pixels 11 would be occupied. The support portion 26 is also referred to as a PS column in the field. The lengthwise direction of some of the support portions 26 is different from that of others. Illustratively, as shown in FIG. 11, the lengthwise direction of some of the support portions 26 is K1, and the lengthwise direction of others of the support portions 26 is K2, and the direction K1 intersects with the direction K2. In other words, the orientation of the support portion 26 is flexibly arranged based on the spiral-shaped arrangement of the first partition portion 1511, to increase the design margin of the support portion 26, and prevent the support portion 26 from being positioned in the region where the partition portion 15 is disposed, which would affect the morphology of the partition portion 15 and the height, strength, etc. of the support portion 26. That is, the spiral design of the first partition portion 151 is satisfied, while the height, length, strength, etc. of the support portion 26 are not affected, ensuring the structural stability of the support portion 26.

Further, in a plurality of the first partition portions 151 adjacent to the support portion 26, the notches of at least some of the first partition portions 151 directly face the support portion 26. By arranging the notches 1511 of at least some of the first partition portions 151 to directly face the support portion 26, the design margin of the support portion 26 can be increased, and the support portion 26 can be prevented from being positioned in the region where the partition portion 15 is disposed, which would affect the morphology of the partition portion 15 and the height, strength, etc. of the support portion 26.

Normally, a plurality of sub-pixels 11 are arranged around one support portion 26. Four sub-pixels 11, i.e., a first sub-pixel 111, a first one of second sub-pixels 112, a third sub-pixel 113, and a second one of the second sub-pixels 112, are arranged in sequence around the support portion 26. In the direction of the surrounding arrangement, it only needs to be ensured that the notches 1511 of the first partition portions 15 corresponding to two adjacent sub-pixels 11 among these four sub-pixels 11 do not both directly face the support portion 26. For example, the notches 1511 of the first partition portions 15 corresponding to the first sub-pixel 111 and the first one of the second sub-pixels 112 do not both directly face the support portion 26. If, among these four sub-pixels 11 in the direction of the surrounding arrangement, the notches 1511 of the first partition portions 15 corresponding to two adjacent sub-pixels 11 both directly face the support portion 26, the leakage current path between these two sub-pixels 11 will be greatly shortened, which is contrary to the purpose of the embodiments of the present disclosure to extend the leakage current path.

In view of this, in the embodiment of the present disclosure, the notch 1511 of the first partition portion 151 corresponding to at least one sub-pixel 11 among the sub-pixels 11 at two opposite sides of the support portion 26 is arranged to directly face the support portion 26. In this way, the support portion 26 can serve as a component for extending the leakage current path between this notch 1511 and other partial notches 1511.

In summary, in the display panel 100 provided by the embodiment of the present disclosure, the leakage current path between at least some pairs of adjacent sub-pixels 11 is extended by providing at least three partition portions 15 between them, to improve leakage current uniformity, thereby resolving the problem of unintended lighting of sub-pixels 11 to the greatest extent and improving the display effect of the display panel 100.

Further, during research it is found that, the current design for alleviate the leakage current of sub-pixels 11 in the display panel 100 is achieved through the partition portions 15. Since the positions of the partition portions 15 and the positions of the support portions 26 cannot overlap, in the case where the partition portions 15 are provided in the display panel 100, the design of the support portions 26 needs to be changed more or less based on the pattern of the partition portions 15. However, the change of the support portions 26 will affect the supporting function of the G FMM, reducing the stability of the display panel 100.

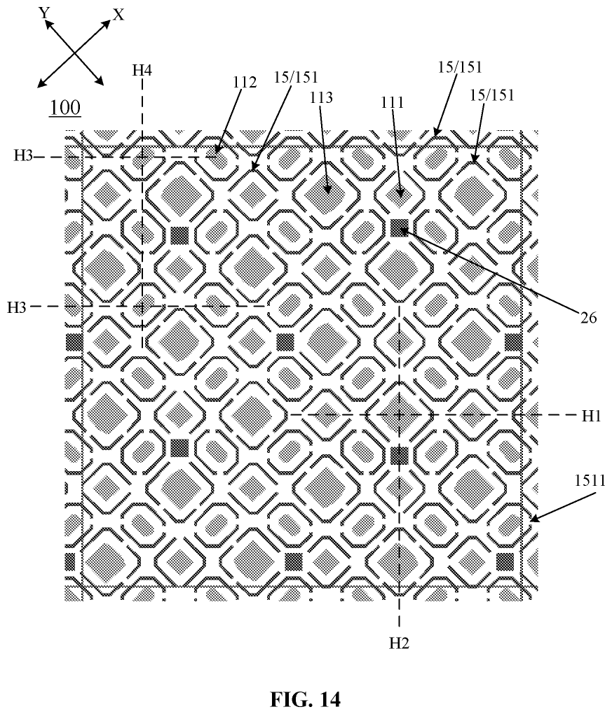

In view of this, in another embodiment of the present disclosure, a display panel is further provided. Reference is made to FIG. 14, which is a partial structural schematic diagram of a display area in yet another display panel provided in an embodiment of the present disclosure. The display panel 100 provided by the embodiment of the present disclosure includes: a substrate 12; a pixel definition layer 13 disposed on one side of the substrate 12, where the pixel definition layer 13 has a plurality of sub-pixel openings 14 for arranging sub-pixels 11, and the pixel definition layer 13 is provided with a plurality of partition portions 15 surrounding the sub-pixels 11.

The sub-pixels 11 include target sub-pixels, and the partition portions 15 include first partition portions 151 surrounding the target sub-pixels.

Each of the first partition portions 151 includes two notches 1511.

A line connecting centers of the two notches 1511 in each of some of the first partition portions 151 intersects with a line connecting centers of the two notches 1511 in each of others of the first partition portions 151.

In one embodiment, in the embodiment of the present disclosure, the lines connecting centers of the two notches 1511 of the first partitions 151 corresponding to the target sub-pixels are changed from being all oriented in a single direction to being oriented in two different directions. Illustratively, the line connecting centers of the two notches 1511 in each of some of the first partition portions 151 corresponding to the target sub-pixels intersects with the line connecting centers of the two notches 1511 in each of others of the first partition portions 151 corresponding to the target sub-pixels. Under the premise of maintaining the uniformity of the leakage current path of the target sub-pixels, the original design of the support portion 26 is maintained, thereby not affecting the supporting function of the G FMM, and improving the stability of the display panel 100.

The target sub-pixels are red sub-pixels and/or green sub-pixels.

As shown in FIG. 14, description is made by taking the case where the target sub-pixels are red sub-pixels (i.e., the first sub-pixels 111 mentioned above) as an example. The extension direction of the line connecting centers of the two notches 1511 in each of some of the first partition portions 151 corresponding to the red sub-pixels is H1, and the extension direction of the line connecting centers of the two notches 1511 in each of others of the first partition portions 151 corresponding to the red sub-pixels is H2, and the direction H1 intersects with the direction H2. In prior art, the lines connecting centers of the two notches 1511 in first partition portions 151 corresponding to the red sub-pixels all extend in the direction H1.

As shown in FIG. 14, description is made by taking the case where the target sub-pixels are green sub-pixels (i.e., the second sub-pixels 112 mentioned above) as an example. The extension direction of the line connecting centers of the two notches 1511 in each of some of the first partition portions 151 corresponding to the green sub-pixels is H3, and the extension direction of the line connecting centers of the two notches 1511 in each of others of the first partition portions 151 corresponding to the green sub-pixels is H4, and the direction H3 intersects with the direction H4. In prior art, the lines connecting centers of the two notches 1511 in first partition portions 151 corresponding to the green sub-pixels all extend in the direction H3.

In one embodiment, as shown in FIG. 14, the sub-pixels 11 further include blue sub-pixels; each of the partition portions 15 corresponding to the blue sub-pixels includes four notches 1511.

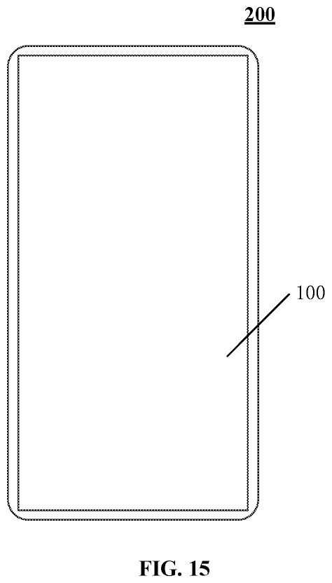

Based on the above embodiments of the present disclosure, correspondingly, a display device is further provided accordingly in an embodiment of the present disclosure. Reference is made to FIG. 15, which is a schematic structural diagram of a display device provided in an embodiment of the present disclosure. The display device 200 includes the display panel 100 according to any one of the above embodiments of the present disclosure. The display device 200 may be any display device having a display function, such as a touch display screen, a mobile phone, a tablet computer, a laptop computer, an electronic paper book, or a television.

The display panel and display device provided by the present disclosure have been described above. Herein, specific examples are used to explain the principles and implementations of the present disclosure. The description of the above embodiments is only for helping understand the method of the present disclosure and the core idea thereof. Meanwhile, for those of ordinary skill in the art, there may be changes to the specific implementations and applications according to the idea of the present disclosure. In summary, the content of this specification should not be construed as a limitation to the present disclosure.

Each embodiment in this specification focuses on the differences from other embodiments, and the same or similar parts between the various embodiments can be referred to each other.

It should also be noted that, in this text, relational terms such as first and second, etc., are only used to distinguish one entity or operation from another entity or operation, and do not necessarily require or imply any such actual relationship or order between these entities or operations. Furthermore, the terms “include” or “comprise” or any other variations thereof are intended to cover non-exclusive inclusion, and a process, method, article, or device that includes a series of elements includes not only those elements but also other elements not explicitly listed, or also includes elements inherent to such process, method, article, or device. Unless defined otherwise, an element defined by the statement “includes a . . . ” does not preclude the existence of additional identical elements in the process, method, article, or device that includes the element.

The above description of the disclosed embodiments enables any person to implement or use the present disclosure. Various modifications to these embodiments will be in the art, and the general principles defined herein may be implemented in other embodiments without departing from the spirit or scope of the present disclosure. Therefore, the present disclosure will not be limited to these embodiments shown herein, but rather should conform to the widest scope consistent with the principles and novel features disclosed herein.

1. A display panel comprising:
a substrate; and
a pixel definition layer disposed on one side of the substrate, wherein the pixel definition layer has a plurality of sub-pixel openings for arranging sub-pixels, and the pixel definition layer is provided with a plurality of partition portions;
wherein for at least some pairs of adjacent sub-pixels, the partition portions provided between the two adjacent sub-pixels are in a quantity of at least three.

2. The display panel according to claim 1, wherein the sub-pixels comprise first sub-pixels, second sub-pixels, and third sub-pixels;
an i-th row of the sub-pixels comprises the first sub-pixels and the second sub-pixels alternately arranged along a first direction; an (i+1)-th row of the sub-pixels comprises the second sub-pixels and the third sub-pixels alternately arranged along the first direction; a j-th column of the sub-pixels comprises the first sub-pixels and the second sub-pixels alternately arranged along a second direction; a (j+1)-th column of the sub-pixels comprises the second sub-pixels and the third sub-pixels alternately arranged along the second direction; and
the first direction intersects the second direction.

3. The display panel according to claim 1, wherein the partition portions comprise first partition portions and second partition portions;
each of the first partition portions comprises a notch, and the first partition portions surrounds the respective sub-pixels;
the second partition portions are each disposed between the first partition portions corresponding to a respective pair of adjacent sub-pixels among at least some pairs of adjacent sub-pixels.

4. The display panel according to claim 3, further comprising a plurality of support portions, wherein
in a plurality of the first partition portions adjacent to one of the support portions, the notches of at least some of the first partition portions directly face the support portion.

5. The display panel according to claim 4, wherein the sub-pixels comprise first sub-pixels, second sub-pixels, and third sub-pixels;
the first sub-pixels are red sub-pixels, the second sub-pixels are green sub-pixels, and the third sub-pixels are blue sub-pixels; and
among the red sub-pixel, the green sub-pixel, and the blue sub-pixel adjacent to the support portion, the notch of the first partition portion corresponding to the red sub-pixel directly faces the support portion, the notch of the first partition portion corresponding to the blue sub-pixel directly faces the support portion, and the notch of the first partition portion corresponding to the green sub-pixel directly faces the second partition portion.

6. The display panel according to claim 5, wherein the second partition portion is disposed between the red sub-pixel and green sub-pixel that are adjacent to each other, and the second partition portion is disposed between the blue sub-pixel and green sub-pixel that are adjacent to each other.

7. The display panel according to claim 4, wherein among the sub-pixels not adjacent to the support portion, the notches of the first partition portions corresponding to two adjacent sub-pixels do not directly face each other.

8. The display panel according to claim 3, wherein the second partition portions are each in a bar shape.

9. The display panel according to claim 1, wherein the partition portions comprise first partition portions;
each of the first partition portions comprises a notch, and the first partition portions surrounds the respective sub-pixels; and
some of the first partition portions are each arranged in a spiral shape.

10. The display panel according to claim 9, wherein the sub-pixels comprise first sub-pixels, second sub-pixels, and third sub-pixels;
the first sub-pixels are red sub-pixels, the second sub-pixels are green sub-pixels, and the third sub-pixels are blue sub-pixels; and
the first partition portions corresponding to the red sub-pixels are each arranged in a spiral shape.

11. The display panel according to claim 10, wherein the partition portions provided between one of the red sub-pixels and one of the green sub-pixels that are adjacent to each other are in a quantity of at least three, the partition portions provided between one of the red sub-pixels and one of the blue sub-pixels that are adjacent to each other are in a quantity of at least three, and the partition portions provided between one of the green sub-pixels and one the blue sub-pixels that are adjacent to each other are in a quantity of two.

12. The display panel according to claim 9, wherein the sub-pixels comprise first sub-pixels, second sub-pixels, and third sub-pixels;
the first sub-pixels are red sub-pixels, the second sub-pixels are green sub-pixels, and the third sub-pixels are blue sub-pixels; and
the first partition portions corresponding to the blue sub-pixels are each in a spiral shape.

13. The display panel according to claim 12, wherein the partition portions provided between one of the blue sub-pixels and one of the green sub-pixels that are adjacent to each other are in a quantity of at least three, the partition portions provided between one of the blue sub-pixels and one of the red sub-pixels that are adjacent to each other are in a quantity of at least three, and the partition portions provided between one of the red sub-pixels and one the green sub-pixels that are adjacent to each other are in a quantity of two.

14. The display panel according to claim 9, wherein the display panel further comprises a plurality of support portions; a lengthwise direction of some of the support portions is different from a lengthwise direction of others of the support portions; and
in a plurality of the first partition portions adjacent to one of the support portions, the notches of at least some of the first partition portions directly face the support portion.

15. The display panel according to claim 1, wherein the partition portions are each a groove portion or a protrusion portion provided on the pixel definition layer.

16. The display panel according to claim 15, wherein some of the partition portions are groove portions provided on the pixel definition layer, and others of the partition portions are protrusion portions provided on the pixel definition layer.

17. The display panel according to claim 1, wherein each of the sub-pixels comprises:
a first electrode disposed on one side of the substrate;
a first light-emitting layer disposed on a side of the first electrode away from the substrate;
a charge generation layer disposed on a side of the first light-emitting layer away from the first electrode;
a second light-emitting layer disposed on a side of the charge generation layer away from the first light-emitting layer; and
a second electrode disposed on a side of the second light-emitting layer away from the charge generation layer.

18. A display panel comprising:
a substrate; and
a pixel definition layer disposed on one side of the substrate, wherein the pixel definition layer has a plurality of sub-pixel openings for arranging sub-pixels, and the pixel definition layer is provided with a plurality of partition portions surrounding the respective sub-pixels;
wherein
the sub-pixels comprise target sub-pixels, and the partition portions comprise first partition portions surrounding the respective target sub-pixels;
each of the first partition portions comprises two notches; and
a line connecting centers of the two notches in each of some of the first partition portions intersects with a line connecting centers of the two notches in each of others of the first partition portions.

19. The display panel according to claim 18, wherein the target sub-pixels are each either a red sub-pixel or a green sub-pixel.

20. The display panel according to claim 19, wherein the sub-pixels further comprise a blue sub-pixel;
the partition portion corresponding to the blue sub-pixel comprises four notches.

21. A display device comprising a display panel, the display panel comprising:
a substrate; and
a pixel definition layer disposed on one side of the substrate, wherein the pixel definition layer has a plurality of sub-pixel openings for arranging sub-pixels, and the pixel definition layer is provided with a plurality of partition portions;
wherein for at least some pairs of adjacent sub-pixels, the partition portions provided between the two adjacent sub-pixels are in a quantity of at least three.
